(19) United States
(12) Patent Application Publication
(10) Pub. No.: US 2024/0349556 A1
(43) Pub. Date: Oct. 17, 2024

(54) DISPLAY SUBSTRATE, DISPLAY PANEL AND DISPLAY DEVICE INCLUDING DISPLAY SUBSTRATE

(71) Applicant: XIAMEN TIANMA DISPLAY TECHNOLOGY CO., LTD., Xiamen (CN)

(72) Inventor: Yong YUAN, Shanghai (CN)

(73) Assignee: XIAMEN TIANMA DISPLAY TECHNOLOGY CO., LTD., Xiamen (CN)

(21) Appl. No.: 18/751,342

(22) Filed: Jun. 24, 2024

(30) Foreign Application Priority Data
Jul. 28, 2023 (CN) 202310942792.3

(51) Int. Cl. H10K 59/131

(52) U.S. Cl. CPC H10K 59/131

(57) ABSTRACT

A display substrate, a display panel and a display device are provided. The display substrate is divided into a display region and a non-display region at least partially surrounding the display region. The display substrate includes data cables and adapter cables arranged in the display region, and connecting cables arranged in the non-display region. A part of the connecting cables are electrically connected to a part of the data cables through the adapter cables, and the remaining connecting cables are electrically connected to the remaining data cables directly. The data cables and the connecting cables are both arranged in the first direction. The data cables are arranged in a same sequence as the connecting cables electrically connected to the data cables. Therefore, performance of the display can be optimized.

The present disclosure claims priority to Chinese Patent Application No. 202310942792.3, titled “DISPLAY SUBSTRATE, DISPLAY PANEL AND DISPLAY DEVICE”, filed on Jul. 28, 2023 with the China National Intellectual Property Administration, which is incorporated herein by reference in its entirety.

### FIELD

The present disclosure relates to the field of display technologies, and in particular to a display substrate, a display panel and a display device.

### BACKGROUND

With ongoing development of display technologies, user demands for performance of displays are increasingly high.

Therefore, how to optimize performance of a display is a problem to be urgently solved.

### SUMMARY

A display substrate, a display panel and a display device are provided according to embodiments of the present disclosure, to optimize the performance of the display.

A display substrate is provided according to embodiments of the present disclosure. The display substrate is divided into a display region and a non-display region. The non-display region at least partially surrounds the display region. The display substrate includes data cables arranged in the display region, adapter cables arranged in the display region, and connecting cables arranged in the non-display region. At least a part of the data cables are electrically connected to the adapter cables. A part of the connecting cables are electrically connected to the part of the data cables through the adapter cables, and the remaining connecting cables are electrically connected to the remaining data cables directly. The data cables are arranged in a first direction, the connecting cables are arranged in the first direction, and the data cables are arranged in a same sequence as the connecting cables electrically connected to the data cables.

In one embodiment, a display panel is provided according to the embodiments of the present disclosure. The display panel includes the display substrate according to the embodiments.

In one embodiment, a display device is provided according to the embodiments of the present disclosure. The display device includes the display panel according to the embodiments.

### BRIEF DESCRIPTION OF THE DRAWINGS

Embodiments of the present disclosure can become more apparent by reading the following detailed description of non-limiting embodiments with reference to the drawings.

The same or similar reference numerals represent the same or similar features throughout the drawings, and the drawings are not drawn to actual scale.

FIG. 1 is a top view of a display substrate according to an embodiment of the present disclosure;

FIG. 2 is a top view of the display substrate according to another embodiment of the present disclosure;

FIG. 3 is a top view showing the display substrate partially according to an embodiment of the present disclosure;

FIG. 4 is a top view showing the display substrate partially according to another embodiment of the present disclosure;

FIG. 5 is a top view of the display substrate according to another embodiment of the present disclosure;

FIG. 6 is a schematic circuit diagram of a pixel driving circuit in the display substrate according to an embodiment of the present disclosure;

FIG. 7 schematically shows layout of the display substrate partially according to an embodiment of the present disclosure;

FIG. 8 schematically shows the display substrate in cross-section according to an embodiment of the present disclosure;

FIG. 9 is a top view of a display panel according to an embodiment of the present disclosure; and

FIG. 10 is a top view of a display device according to an embodiment of the present disclosure.

The numeral references in the drawings:
100 display substrate;
AA display region; NA non-display region; BA binding region;
A1 central region; A2 margin region;
10 data cable; 11 first data cable; 12 second data cable;
20 adapter cable; 21 first segment; 22 second segment;
connecting cable; 31 first connecting cable; 32 second connecting cable;
40 data signal terminal;
50 auxiliary cable; 51 first auxiliary cable; 52 second auxiliary cable;
60 pixel driving circuit;
200 display panel; and
1000 display device.

### DETAILED DESCRIPTION OF EMBODIMENTS

The embodiments of the present disclosure are described in detail below. In order to clearly explain the purpose, the embodiments of the present disclosure, the present disclosure is further described in detail below in conjunction with the accompanying drawings and embodiments. It should be understood that the embodiments described herein are for explaining the present disclosure instead of limiting the present disclosure. The present disclosure can be practiced without some of these details. The following description of embodiments is merely intended to provide a better understanding of the present disclosure by examples.

It should be noted that relational terms such as first and second herein are only used to distinguish one entity or operation from another instead of necessitating or implying a relationship or sequence between entities or operations. Furthermore, the terms “comprise”, “include” or any other variations thereof are intended to cover a non-exclusive inclusion, and a process, method, article, or device including a list of elements includes not only those elements but also other elements not expressly listed, or also includes elements inherent in the process, method, article, or device. Without further limitations, an element defined by the statement “comprising . . . ” does not exclude the presence of additional same elements in the process, method, article or device.

It should be understood that a layer or region described as being “on” or “above” another may be directly or indirectly on the other, and may be under or below the other in case of reversal.

It should be understood that the term “and/or” herein is only for describing three cases. For example, A and/or B indicates a case that A exists alone, a case that A and B exist simultaneously, or a case that B exists alone. In addition, the character “/” herein generally links two alternatives.

In the embodiments of the present disclosure, the term “electrical connection” indicates direct or indirect electrical connection between two components.

Various modifications and changes can be made to the present disclosure without departing from the embodiments of the present disclosure. Therefore, the present disclosure intends to cover the modifications and changes falling within the embodiments of the claims (embodiments to be protected) and their equivalents. It should be noted that the embodiments of the present disclosure may be combined with each other if there is no contradiction.

A display substrate, a display panel and a display device are provided according to embodiments of the present disclosure, and are described in embodiments below with reference to the drawings.

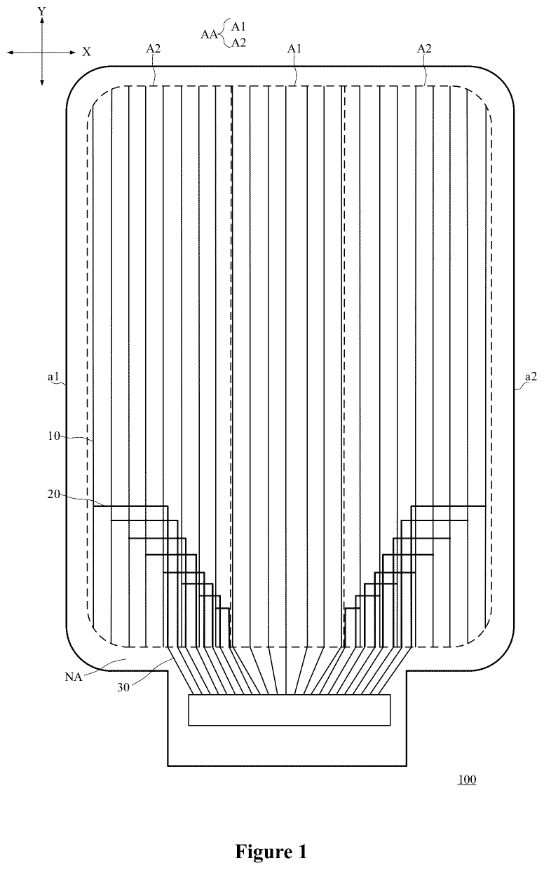

As shown in FIG. 1, the display substrate 100 is provided with a display region AA and a non-display region NA at least partially surrounding the display region AA. The display substrate 100 is also provided with data cables 10, adapter cables 20 and connecting cables 30.

The data cables 10 are arranged in the display region AA, along a first direction X, and extending in a second direction Y The first direction X intersects the second direction Y For example, the first direction X is a row direction and the second direction Y is a column direction. In one embodiment, the second direction Y is the row direction and the first direction X is the column direction.

The adapter cables 20 are arranged in the display region AA. At least a part of the data cables 10 are electrically connected to the adapter cables 20.

The connecting cables 30 are arranged in the non-display region NA. Some connecting cables 30 are electrically connected to some the data cables 10 through the adapter cables 20, and the other connecting cables 30 are directly electrically connected to the other part of the data cables 10. The connecting cables 30 are arranged in the first direction X and do not intersect. That is, orthographic projections of the connecting cables 30 on a plane where the display substrate is arranged do not overlap. For example, the connecting cables 30 are in a fan shaped arrangement. The connecting cable 30 is configured to transmit a data signal to the data cable 10 electrically connected to the connecting cable 30.

It should be noted that the expression “the connecting cable 30 is directly electrically connected to the data cable 10” herein indicates no adapter cable 20 between the data cable 10 and the connecting cable 30. When the connecting cable 30 is arranged on a different layer than the data cable 10, the expression “the connecting cable 30 is directly electrically connected to the data cable 10” indicates that the connecting cable 30 is electrically connected to the data cable 10 through a through hole. In other embodiments, the expression “the connecting cable 30 is directly electrically connected to the data cable 10” indicates that the connecting cable 30 is electrically connected to the data cable 10 via a switch.

For example, the display region AA is divided into a central region A1 and a margin region A2 beside the central region A1 in the first direction X. The margin region A2 is closer to a margin of the display substrate 100 in the first direction X. The data cables 10 arranged in the margin region A2 are electrically connected to the adapter cables 20, and thence to some of the connecting cables 30. The data cables 10 arranged in the central region A1 are electrically connected to the remaining connecting cables 30 directly.

The data cables 10 are arranged in the same sequence as the connecting cables 30 electrically connected to the data cables 10. For example, the display substrate 100 has a first edge a1 and a second edge a2 that are opposite in the first direction X. In FIG. 1, the first edge a1 is a left margin and the second edge a2 is a right margin. In a direction parallel to the first direction X and pointing from the first edge a1 to the second edge a2, a first data cable 10 to an n^{th} data cable 10 in the display region AA are arranged in sequence. For example, the data cables 10 are electrically connected to the connecting cables 30, respectively. In the direction parallel to the first direction X and pointing from the first edge a1 to the second edge a2, a first connecting cable 30 to an n^{th} connecting cable 30 in the non-display region NA are arranged in sequence. An i^{th} data cable is electrically connected to an i^{th} connecting cable 30, and i ranges from 1 to n.

In the display substrate according to the embodiments of the present disclosure, some of the data cables 10 are electrically connected to some connecting cables 30 through the adapter cables 20, while the remaining data cables 10 are electrically connected to the remaining connecting cables 30 directly. The data cables 10 are arranged in the same sequence as the connecting cables 30. Therefore, the problem of disarray when transmitting data signals to the data cables 10 due to the fact that the connecting cables 30 are arranged in a different sequence than the data cables 10, to facilitate improvement in performance.

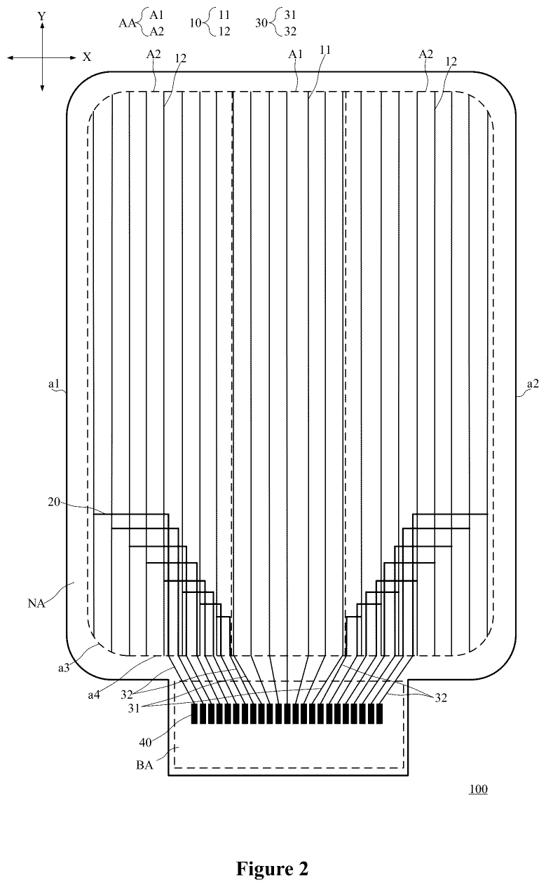

In some embodiments, as shown in FIG. 2, the non-display region NA includes a binding region BA in which data signal terminals 40 are arranged along the first direction X. The connecting cables 30 are electrically connected to the data signal terminals 40, and are configured to transmit data signals provided by the data signal terminals 40 to the data cables 10. The data cables 10 are arranged in the same sequence as the data signal terminals 40 electrically connected to the data cables 10. That is, the data cables 10, the connecting cables 30 and the data signal terminals 40 are arranged in the same sequence.

For example, the data cables 10 are electrically connected to the connecting cables 30, and thence to the data signal terminals 40, respectively. In the direction parallel to the first direction X and pointing from the first edge a1 to the second edge a2, a first data cable 10 to an n^{th} data cable 10 in the display region AA are arranged in sequence, a first connecting cable 30 to an n^{th} connecting cable 30 in the non-display region NA are arranged in sequence, and a first data signal terminal 40 to an n^{th} data signal terminal 40 in the binding region BA are arranged in sequence. An i^{th} data cable is electrically connected to an i^{th} connecting cable 30, and thence to an i^{th} data signal terminal 40. i ranges from 1 to n.

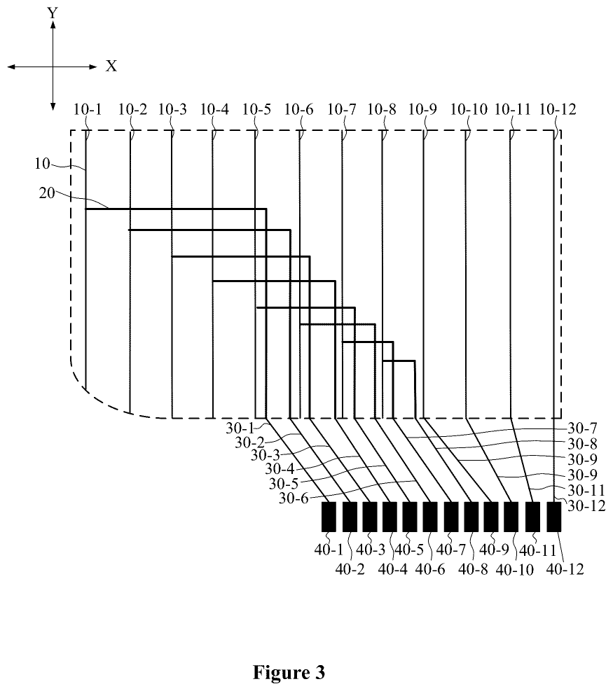

Further details about the data cables 10, the connecting cables 30 and the data signal terminals 40 being arranged in the same sequence are given below. In the direction parallel to the first direction X and pointing from the first edge a1 to the second edge a2, as shown in FIG. 3, a first data cable 10-1 to a 12th data cable 10-12 are arranged in sequence, a first connecting cable 30-1 to a 12th connecting cable 30-12 are arranged in sequence, and a first data signal terminal 40-1 to a 12th data signal terminal 40-12 are arranged in sequence. The first data cable 10-1 is electrically connected to the first data signal terminal 40-1 through the first connecting cable 30-1, the second data cable 10-2 is electrically connected to the second data signal terminal 40-1 through the second connecting cable 30-2, . . . , and the 12th data cable 10-12 is electrically connected to the 12th data signal terminal 40-12 through the 12th connecting cable 30-12.

For example, the data signal terminals 40 are electrically connected to a display driver chip. The display driver chip is configured to provide the data signals.

In the embodiments of the present disclosure, the data cables 10, the connecting cables 30 and the data signal terminals 40 are arranged in the same sequence. Therefore, the problem of disarray when the display driver chip transmits the data signals to the data cables 10 through the data signal terminals 40 and the connecting cables 30 due to the fact that the data cables 10, the connecting cables 30 and the data signal terminals 40 are arranged in different sequences, to simplify driving timing of the display driver chip and facilitating improvement in performance.

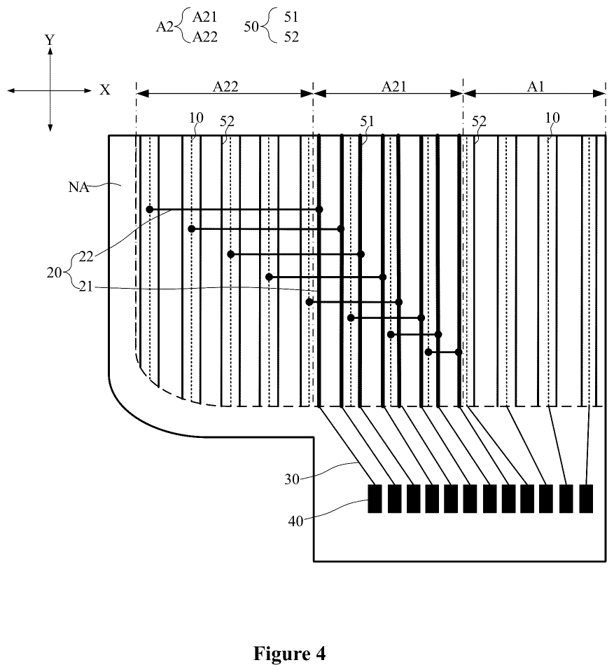

In some embodiments, as shown in FIG. 4, the display substrate 100 is also provided with auxiliary cables 50. In a case that the data cables 10 are n in number, the auxiliary cables 50 are m*n in number. m and n are integers greater than or equal to 2.

The auxiliary cable 50 extends in the same direction as the data cable 10. The adapter cables each 20 include a first segment 21 extending in the same direction as the auxiliary cable 50. For example, the data cable 10, the auxiliary cable 50, and the first segment 21 all extend along the second direction Y

The m*n auxiliary cables 50 are evenly arranged in the display region AA. At least part of the auxiliary cables 50 are partially integrally formed with the respective first segments 21. That is, at least part of the auxiliary cables 50 partially double as the first segments 21. For example, there are j adapter cables 20, and therefore j auxiliary cables 50 partially double as the j first segments 21 of the j adapter cables 20, respectively.

In FIG. 4, the data cable 10 is shown as a dotted line, and the auxiliary cable 50 is shown as a solid line, in order to clearly distinguish the data cable 10 and the auxiliary cable 50. The auxiliary cable 50 doubling as the first segment 21 is illustrated as a thick solid line, and another auxiliary cable 50 is illustrated as a thin solid line, in order to clearly distinguish the auxiliary cable 50 that doubles as the first segment 21 and the other auxiliary cable 50. In addition, the electrical connection between cables is illustrated as a black dot.

In the embodiments of the present disclosure, at least part of the auxiliary cables 50 partially double as the first segments 21, and therefore it is unnecessary to arrange additional cables as the first segments 21. In addition, the m*n auxiliary cables 50 are evenly distributed in the display region AA, to display an image evenly.

In some embodiments, as shown in FIG. 4, the adapter cables 20 each include a second segment 22 extending along the first direction X. One end of the second segment 22 is electrically connected to the data cable 10, and the other end of the second segment 22 is electrically connected to the auxiliary cable 50.

For example, the second segment 22 is arranged on a different film layer than the data cable 10, and is electrically connected to the data cable 10 through a via hole. The second segment 22 and the auxiliary cable 50 can be arranged on different film layers, and the second segment 22 and the auxiliary cable 50 can be electrically connected through the via hole.

For example, among the data cables arranged on a same side of a center line of the display substrate, the data cable 10 closer to the center line is electrically connected the first segment closer to the center line. Here, the “center line” refers to a line passing through a center of the display substrate and extending along the second direction.

For example, the (i+1)^{th} data cable 10 is closer to the center line than the i^{th} data cable 10. The i^{th} data cable 10 is electrically connected to the first segment 21 of the i^{th} adapter cable 20, and the (i+1)^{th} data cable 10 is electrically connected to the first segment 21 of the (i+1)^{th} adapter cable 20. The first segment 21 of the (i+1)^{th} adapter cable 20 is closer to the center line than the first segment 21 of the i^{th} adapter cable 20.

In some embodiments, m auxiliary cables 50 are arranged between two adjacent data cables 10. In this way, the m*n auxiliary cables 50 can be evenly arranged among the n data cables 10, to display an image evenly.

For example, an orthographic projection of the auxiliary cable 50 on the plane where the display substrate is arranged does not overlap an orthographic projection of the data cable 10 on the plane where the display substrate is arranged.

For example, m is equal to 2, and therefore two auxiliary cables 50 are arranged between two adjacent data cables 10.

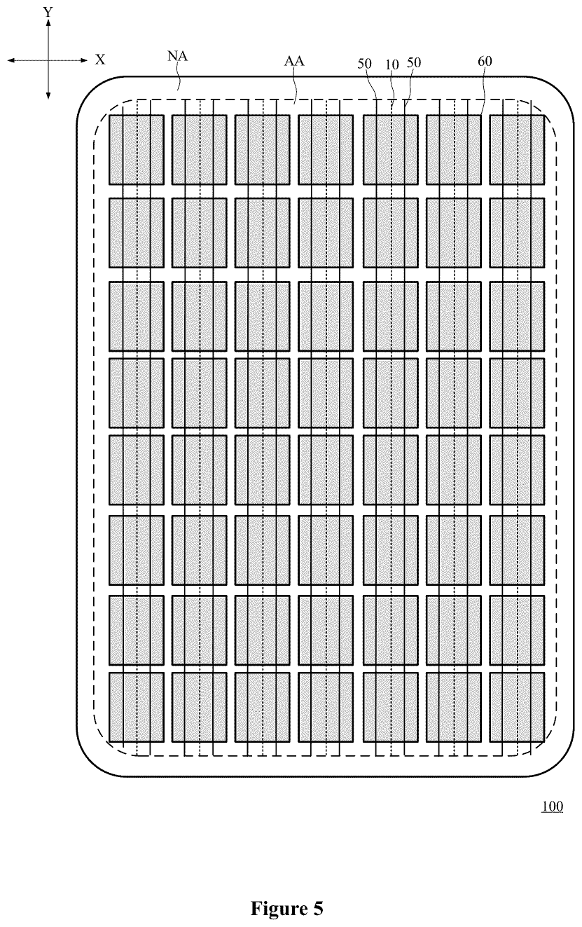

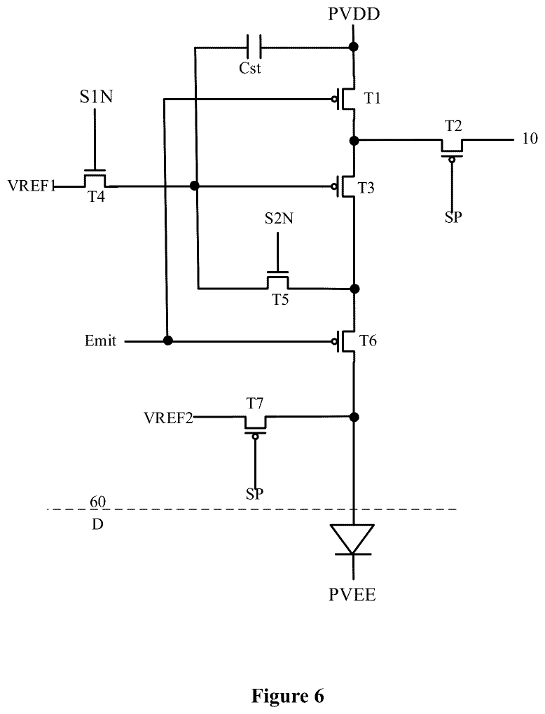

In some embodiments, as shown in FIG. 5, the display substrate 100 further includes pixel driving circuits 60. As shown in FIG. 6, the pixel driving circuit 60 is configured to drive a light emitting element D to emit light.

The pixel driving circuits 60 are arranged in rows and columns. The columns are connected to the data cables 10, respectively.

In some embodiments, m is equal to 2, that is, each column corresponds to two auxiliary cables 50. The corresponding data cable 10 is sandwiched between the two auxiliary cables in the first direction.

It should be noted that, the data cable 10 is shown as a dotted line and the auxiliary cable 50 is shown as a solid line in FIG. 6, in order to clearly distinguish the data cable 10 and the auxiliary cable 50.

For example, the orthographic projection of the data cable 10 on the plane where the display substrate is arranged overlaps the orthographic projection of the pixel driving circuit 60 on the plane where the display substrate is arranged. The orthographic projection of the auxiliary cable 50 on the plane where the display substrate is arranged overlaps the orthographic projection of the pixel driving circuit 60 on the plane where the display substrate is arranged.

For example, as shown in FIG. 6, the pixel driving circuit 60 includes transistors T1 to T7 and a storage capacitor Cst. A first electrode of a transistor T1 is electrically connected to the first power cable PVDD, and a second electrode of the transistor T1 is electrically connected to a first electrode of a driving transistor T3. A first electrode of a transistor T6 is electrically connected to a second electrode of the driving transistor T3, and a second electrode of the transistor T6 is electrically connected to an anode of the light emitting element D. Gate electrodes of the transistor T1 and the transistor T6 are electrically connected to a light emitting control signal cable Emit. The first power cable PVDD is configured to transmit a positive voltage signal.

A first electrode of a transistor T2 is electrically connected to the data cable 10, a second electrode of the transistor T2 is electrically connected to the first electrode of the driving transistor T3, and a gate electrode of the transistor T2 is electrically connected to a first scanning cable SP.

A first electrode of the transistor T4 is electrically connected to a reset signal cable VREF1, a second electrode of the transistor T4 is electrically connected to a gate electrode of the driving transistor T3, and a gate electrode of the transistor T4 is electrically connected to a second scanning cable SiN. The reset signal cable VREF1 is configured to transmit a negative voltage signal.

A first electrode of a transistor T5 is electrically connected to the second electrode of the driving transistor T3, a second electrode of the transistor T5 is electrically connected to the gate electrode of the driving transistor T3, and the gate electrode of the transistor T5 is electrically connected to a third scanning cable S2N.

A first electrode of the transistor T7 is electrically connected to an initialization signal cable VREF2, a second electrode of the transistor T7 is electrically connected to the anode of the light emitting element D, and a gate electrode of the transistor T7 is electrically connected to the first scanning cable SP. The initialization signal cable VREF2 is configured to transmit a negative voltage signal.

A first electrode of a storage capacitor Cst is electrically connected to the gate electrode of the driving transistor T3, and a second electrode of the storage capacitor Cst is electrically connected to the first power cable PVDD.

A cathode of the light emitting element D is electrically connected to the second power cable PVEE. The second power cable PVEE is configured to transmit a negative voltage signal.

The pixel driving circuit 60 is not limited to that as shown in FIG. 6 in structure. For example, the pixel driving circuit 60 further includes a transistor for writing a bias modification signal.

In addition, in FIG. 6, the transistors T1, T2, T3, T6 and T7 each are the P-type transistor, and the transistors T4 and T5 each are the N-type transistor, which are not limited thereto.

In some embodiments, the m*n auxiliary cables 50 are arranged on the same film layer, and therefore can be patterned during preparation, to simplify the preparation.

The auxiliary cables 50 are arranged on a different film layer than the data cables 10. As mentioned above, at least part of the auxiliary cables 50 partially double as the first segments 21, that is, the part of the auxiliary cables 50 are configured to transmit data signals. The auxiliary cables 50 are arranged on a different film layer than the data cables 10, to reduce interference between data signals, to improve the performance in display.

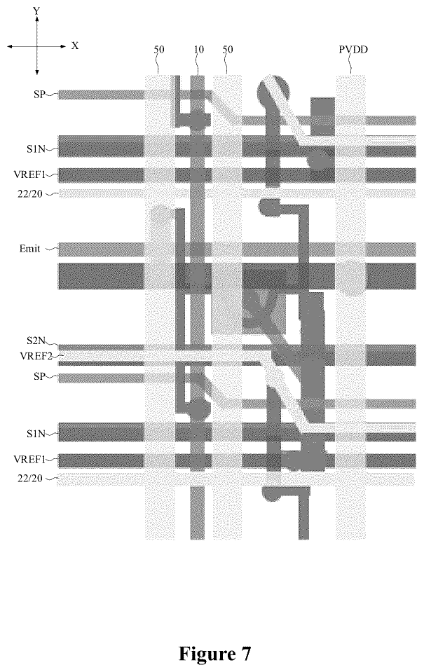

In some embodiments, as shown in FIG. 7, the display substrate further includes the first power cable PVDD extending along the second direction Y The first power cable PVDD is configured to transmit a positive voltage signal, and the auxiliary cables 50 are arranged on the same layer as the first power cable PVDD.

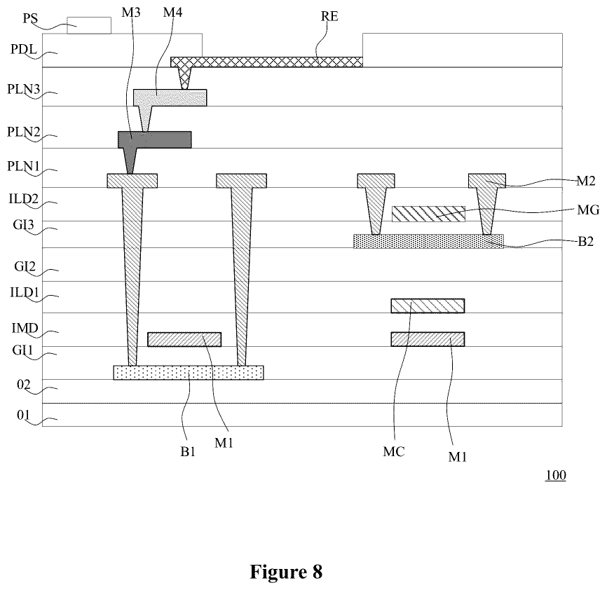

For example, as shown in FIG. 8, the display substrate 100 includes a substrate 01, a buffer layer 02, a first semiconductor layer B1, a first metal layer M1, a capacitive metal layer MC, a second semiconductor layer B2, a gate metal layer MG, a second metal layer M2, a third metal layer M3, a fourth metal layer M4 and an anode layer RE in its thickness direction Z.

For example, he first semiconductor layer B1 is made of silicon, for example, low-temperature polysilicon. The second semiconductor layer B2 is made of oxide semiconducting material, for example, indium gallium zinc oxide.

The insulating layer of the display substrate 100 includes a first gate insulating layer GI1, a capacitor insulating layer IMD, a first interlayer dielectric layer ILD1, a second gate insulating layer GI2, a third gate insulating layer GI3, a second interlayer dielectric layer ILD2, a first planarization layer PLN1, a second planarization layer PLN2 and a third planarization layer PLN3.

The display substrate 100 further includes a pixel defining layer PDL and a supporting pillar PS.

For example, the data cables 10 are arranged on the second metal layer M2. The auxiliary cables 50 are arranged on the fourth metal layer M4. The first power cable PVDD extending along the second direction Y is arranged on the fourth metal layer M4.

The second segments 22 of the adapter cables 20 are arranged on the third metal layer M3.

The initialization signal cable VREF2 is arranged on the third metal layer M3. The reset signal cable VREF1 is arranged on the capacitive metal layer MC.

The scanning cable SP and the light emitting control signal cable Emit are arranged on the first metal layer M1. The scanning cables SiN and S2N are arranged on the gate metal layer MG.

An active layer of the P-type transistor is arranged on the first semiconductor layer B1, and an active layer of the N-type transistor is arranged on the second semiconductor layer B2.

It should be noted that FIG. 8 shows the display substrate that is made of the low temperature polycrystalline oxide (LTPO). In other embodiments, the display substrate is made of low temperature polysilicon (LTPS). The display substrate made of LTPS does not include the second semiconductor layer B2, the gate metal layer MG, the second gate insulating layer GI2, the third gate insulating layer GI3, and the interlayer dielectric layer ILD2 as shown in FIG. 8.

In some embodiments, as shown in FIG. 4, the auxiliary cables 50 are grouped into first auxiliary cables 51 and second auxiliary cables 52. The first auxiliary cables 51 are partially integrally formed with the first segments 21 of the adapter cables 20, respectively. That is, the first auxiliary cables 51 instead of the second auxiliary cables 52 partially double as the first segments 21 of the adapter cables 20, respectively.

For example, the margin region A2 of the display region includes a first sub-region A21 and a second sub-region A22. The first sub-region A21 and the second sub-region A22 are arranged in the first direction X, and the first sub-region A21 is arranged between the central region A1 and the second sub-region A22. The first auxiliary cables 51 are arranged in the first sub-region A1, and the second auxiliary cables 52 are arranged in the second sub-region A22 and the central region A1.

The data cables 10 are n in number, the auxiliary cables 50 are m*n in in number, and a ratio of the data cables 10 to the auxiliary cables 50 is 1:m. A larger m reduces the first auxiliary cables 51 doubling as the first segments 21 in size in the first direction X, that is, reduces the first sub-region A1 in size in the first direction X. Accordingly, the auxiliary cables of the display substrate are greater in number. In some embodiments, m is equal to 2 in order for higher pixel density.

In some embodiments, the second auxiliary cables 52 are electrically connected to a constant voltage signal cable of the display substrate, to display an image evenly.

In some embodiments, the second auxiliary cables 52 are electrically connected to the second power cable PVEE, and therefore are configured to transmit signals on the second power cable PVEE. The second auxiliary cable 52 serves as the second power cable PVEE, that is, the voltage drop of the second power cable PVEE is reduced, to display an image evenly and reducing power consumption.

In other embodiments, the second auxiliary cables 52 are electrically connected to one of the first power cable PVDD, the reset signal cable VREF1, and the initialization signal cable VREF2.

In some embodiments, as shown in FIG. 2, the data cables 10 are grouped into first data cables 11 and second data cables 12. The first data cables 11 are arranged in the central region A1, and the second data cables 12 are arranged in the margin region A2.

The connecting cables 30 are grouped into first connecting cables 31 and second connecting cables 32. The second connecting cables 32 are electrically connected to the second data cables 12 through the adapter cables 20. The first connecting cables 31 are electrically connected to the first data cables 11 directly. In the first direction X, the first data cables 11 are sandwiched between the second data cables 12 and the first connecting cables 21 are sandwiched between the second connecting cables 32.

It should be noted that “the first connecting cable 31 being electrically connected to the first data cable 11 are directly” herein indicates that the first connecting cable 31 is electrically connected to the first data cable 11 through no adapter cable 20.

In the embodiments of the present disclosure, the first data cables 11 are sandwiched between the second data cables 12 and the first connecting cables 21 are sandwiched between the second connecting cables 32 in the first direction X, and the data cables 10 are arranged in the same sequence as the connecting cables 30 electrically connected to the data cables 10. Furthermore, the second connecting cable 32 does not intersect with the first connecting cable 31.

In some embodiments, as shown in FIG. 2, an edge of the display region AA includes a corner edge a3 and a straight edge a4 extending along the first direction X. The second data cable 12 corresponds to the corner edge a3 and a part of the straight edge a4, and the first data cable 11 corresponds to the straight edge a4 only.

For example, in the display region, the margin region A2 is surrounded by the corner edge a3 and a part of the straight edge a4 is, and the central region A1 is surrounded by the other part of the straight edge a4. The second data cables 12 are arranged in the margin region A2, and the first data cables 11 are arranged in the central region A1.

In some embodiments, the first data cables 11 are more than a half of the second data cables 12.

In other embodiments, the first data cables 11 are not more than a half of the second data cables 12.

It should be noted that transistor in the embodiments of the present disclosure is an N-type transistor or a P-type transistor. The N-type transistor switches on by a high level, and switches off by a low level. That is, when the gate potential of the N-type transistor is at the high level, a conducting path is established between the first electrode and the second electrode of the N-type transistor. When the gate potential of the N-type transistor is at the low level, the first electrode is cut off from the second electrode of the N-type transistor. The P-type transistor witches on by a low level, and witches off by a high level. That is, when the gate potential of the P-type transistor is at the low level, a conducting path is established between the first electrode and the second electrode of the P-type transistor. When the gate potential of the P-type transistor is at the high level, the first electrode is cut off from the second electrode of the P-type transistor. In practice, the gate electrode of each of the transistors serves as its control electrode. Further, the first electrode serves as the source electrode and the second electrode serves as the drain electrode, or the first electrode serves as the drain electrode and the second electrode serves as the source electrode, depending on a signal received by the gate electrode.

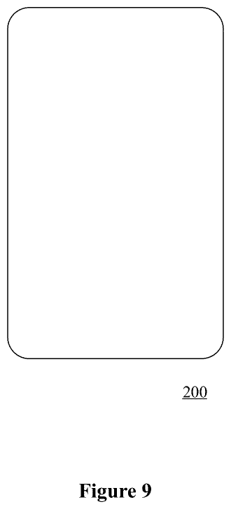

In one embodiment, a display panel is also provided according to the present disclosure. FIG. 9 is a schematic structural diagram illustrating the display panel. As shown in FIG. 9, the display panel 200 according to the embodiment of the present disclosure includes the display substrate 100 described above. The display panel as shown in FIG. 9 may be an organic light emitting diode (OLED) display panel.

Other embodiments of the present disclosure, the display panel is a micro light emitting diode (Micro LED) display panel, a quantum dot display panel, or the like.

With the display panel according to the embodiments of the present disclosure, a part of the data cables are electrically connected to a part of connecting cables through adapter cables, and the other part of the data cables are electrically connected to the other part of the connecting cables directly. The data cables are arranged in the same sequence as the connecting cables. Therefore, the problem of disarray when transmitting data signals to the data cables 10 due to the fact that the connecting cables are arranged in a different sequence than the data cables, to facilitate improvement in performance.

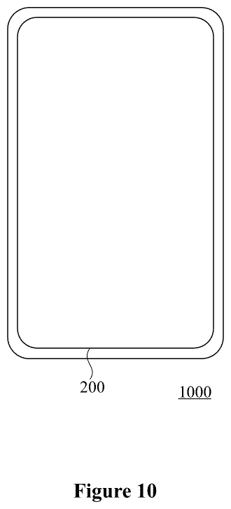

In one embodiment, a display device is also provided according to the present disclosure. The display device includes the display panel as described above. FIG. 10 illustrates the display device. The display device 1000 as shown in FIG. 10 includes the display panel 200 according to the embodiments of the present disclosure. The display device 1000 as shown in FIG. 10 is described by a mobile phone. It should be understood that the display device according to embodiments of the present disclosure may be a wearable product, a computer, a television, a vehicle-mounted display device or the like, which are not limited herein. The display device according to the embodiments of the present disclosure has the same beneficial effects as the display panel according to the embodiments of the present disclosure. For further details, reference can be made to the description of the display panel in the above embodiments. Therefore, the display device is not detailed herein.

The embodiments of the present disclosure described above fail to describe all details, and thus the present disclosure is not limited to these embodiments. Many modifications and variations may be made in light of the above description. These embodiments are described herein to better explain the principles and practical applications of the present disclosure. This application is limited only by the claims and their full scope and equivalents.

1. A display substrate, provided with a display region and a non-display region at least partially surrounding the display region, comprising:
data cables arranged in the display region;
adapter cables arranged in the display region, wherein at least a part of the data cables are electrically connected to the adapter cables; and
connecting cables arranged in the non-display region, wherein a part of the connecting cables are electrically connected to the part of the data cables through the adapter cables, and the remaining connecting cables are electrically connected to the remaining data cables directly, wherein the data cables are arranged in a first direction, the connecting cables are arranged in the first direction, and the data cables are arranged in a same sequence as the connecting cables electrically connected to the data cables.

2. The display substrate according to claim 1, wherein
the data cables are n in number, and n is an integer greater than or equal to 2;
the display substrate further comprises m*n auxiliary cables, m is an integer greater than or equal to 2, the auxiliary cables extend in a same direction as the data cables, and the m*n auxiliary cables are evenly distributed in the display region;
the adapter cables comprise respective first segments extending in a same direction as the auxiliary cables; and
at least part of the auxiliary cables are partially integrally formed with the first segments, respectively.

3. The display substrate according to claim 2, wherein
the adapter cables comprise respective second segments extending along the first direction, and the second segments are electrically connected to the data cables at first ends, and are electrically connected to the auxiliary cables at second ends, respectively.

4. The display substrate according to claim 2, wherein
m auxiliary cables are arranged between two adjacent data cables.

5. The display substrate according to claim 2, further comprising:
pixel driving circuits arranged in columns respectively connected to the data cables; and
m is equal to 2, each column corresponds to two of the auxiliary cables, wherein the corresponding data cable is sandwiched between the two auxiliary cables in the first direction.

6. The display substrate according to claim 2, wherein
the auxiliary cables are arranged on a different film layer than the data cables, and the m*n auxiliary cables are arranged on a same film layer.

7. The display substrate according to claim 6, further comprising:
a first power cable extending along a second direction, wherein the first power cable is configured to transmit a positive voltage signal, the second direction intersects the first direction, and the auxiliary cables are arranged on a same film layer as the first power cable.

8. The display substrate according to claim 2, wherein
the auxiliary cables are grouped into first auxiliary cables and second auxiliary cables;
the first auxiliary cables are partially integrally formed with the first segments of the adapter cables, respectively; and
the second auxiliary cables are electrically connected to a constant voltage signal cable.

9. The display substrate according to claim 8, further comprising:
a second power cable electrically connected to the second auxiliary cables and configured to transmit a negative voltage signal.

10. The display substrate according to claim 1, wherein
the data cables are grouped into first data cables and second data cables, the connecting cables are grouped into first connecting cables and second connecting cables, the second connecting cables are electrically connected to the second data cables through the adapter cables, and the first connecting cables are electrically connected to the first data cables directly; and
the first data cables are sandwiched between the second data cables and the first connecting cables are sandwiched between the second connecting cables, in the first direction.

11. The display substrate according to claim 10, wherein
the display region comprises an edge comprising a corner edge and a straight edge extending along the first direction, the second data cables each correspond to the corner edge and a part of the straight edge, and the first data cables each correspond to the straight edge only.

12. The display substrate according to claim 10, wherein
the first data cables are more than a half of the second data cables.

13. The display substrate according to claim 1, wherein
the non-display region comprises a binding region, data signal terminals arranged in the binding region along the first direction, and the connecting cables are connected to the data signal terminals, respectively; and
the data cables are arranged in the same sequence as the data signal terminals electrically connected to the data cables.

14. A display panel, comprising:
the display substrate according to claim 1.

15. A display device, comprising:
the display panel according to claim 14.
